(19) United States
(12) Patent Application Publication
(10) Pub. No.: US 2025/0223688 A1
(43) Pub. Date: Jul. 10, 2025

(54) METHOD AND APPARATUS FOR AREA-SELECTIVE DEPOSITION

(71) Applicant: ASM IP Holding B.V., Almere (NL)

(72) Inventors: Chao Zhang, London (CA); Mikko Ritala, Espoo (FI)

(21) Appl. No.: 19/008,803

(22) Filed: Jan. 3, 2025

Related U.S. Application Data
(60) Provisional application No. 63/617,564, filed on Jan. 4, 2024.

(51) Int. Cl. C23C 16/04; C23C 16/18; C23C 16/458

(52) U.S. Cl. CPC C23C 16/04; C23C 16/18; C23C 16/458

(57) ABSTRACT

The current disclosure relates to methods and apparatuses for the manufacture of semiconductor devices. In the disclosure, a material comprising metal is selectively deposited on a substrate by a cyclic deposition process. The deposition method comprises providing a substrate in a reaction chamber, wherein the substrate comprises a first surface comprising a first material, and a second surface comprising a second material. A metal precursor comprising a metal aminoalkoxide is provided in the reaction chamber in vapor phase to deposit a material comprising metal on the first surface relative to the second surface.

### CROSS-REFERENCE TO RELATED APPLICATION(S)

This application claims the benefit of U.S. Provisional Application 63/617,564 filed on Jan. 4, 2024, the entire contents of which is incorporated herein by reference.

### FIELD OF INVENTION

The present disclosure relates to methods and apparatuses for selectively deposition a material comprising a metal on a surface of a substrate, to layers and structures including the material comprising a metal, and to vapor deposition apparatuses for depositing the material comprising metal. The methods and apparatuses may find use, for example in the manufacture of semiconductor devices.

### BACKGROUND OF THE DISCLOSURE

Advances in semiconductor manufacturing present a need for new processing approaches. Conventionally, patterning in semiconductor processing involves subtractive processes, in which blanket layers are deposited, masked by photolithographic techniques, and etched through openings in the mask. Additive patterning is also known, in which masking steps precede deposition of the materials of interest, such as patterning using lift-off techniques or damascene processing. In most cases, expensive multi-step lithographic techniques are applied for patterning.

While extreme ultraviolet (EUV) lithography and multi-patterning techniques may enable future scaling, pattern misalignment, such as edge placement error (EPE), may become a bottleneck in integrated circuit (IC) fabrication at advanced technology nodes. To mitigate this challenge, self-aligned thin-film patterning has received extensive research interest.

Area-selective atomic layer deposition (AS-ALD) is a self-aligned vapor deposition process that exploits local chemical differences on a substrate surface to direct material growth on desired substrate areas while no growth occurs on the others. The chemical differences on a substrate surface either already exist, for example, on IC devices (semiconductors, insulators, metals) or are specifically created. AS-ALD presents an alternative for patterning, and it has gained increasing interest among semiconductor manufacturers. AS-ALD can be highly beneficial in various ways. Significantly, it could allow a decrease in lithography steps, reducing the cost of processing. One of the challenges with selective deposition is that selectivity for deposition processes are often not high enough to accomplish the goals of selectivity. Surface pretreatment is sometimes available to either inhibit or encourage deposition on a given surface, but often such treatments themselves call for lithography to have the treatments applied or remain only on the surface to be treated.

Thus, there is need in the art for more versatile, and especially simple, selective deposition schemes to deposit different materials on various surface material combinations for semiconductor structures.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In one aspect, a method for selectively depositing material comprising metal on a substrate by cyclic deposition is disclosed. The method comprises providing a substrate in a reaction chamber, wherein the substrate comprises a first surface comprising a first material, and a second surface comprising a second material. The method further describes providing a metal aminoalkoxide precursor into the reaction chamber in vapor phase to deposit a material comprising a metal on the first surface relative to the second surface. The metal aminoalkoxide precursor comprises an amino group and an alkoxide group, and the first material comprises a noble metal.

In some embodiments, the metal in the metal aminoalkoxide precursor is a transition metal.

In some embodiments, the transition metal is selected from the group consisting of copper, nickel, iron, manganese, chromium, zinc and cobalt.

In some embodiments, the aminoalkoxide ligand is a bidentate ligand.

In some embodiments, the amino group and the alkoxide group are bonded to the metal.

In some embodiments, the aminoalkoxide precursor comprises at least one aminoalkoxide ligand.

In some embodiments, wherein the aminoalkoxide precursor comprises two aminoalkoxide ligands.

In some embodiments, the metal precursor comprises a ligand selected from the list consisting of dmap, dmamp, emamp, deamp, emamb, deamb and dmaeb.

In some embodiments, the metal precursor is selected from the group consisting of the metal precursor is selected from the group consisting of Ni(dmap)₂, Ni(dmamp)₂, Ni(emamp)₂, Ni(deamp)₂, Ni(emamb)₂, Ni(deamb)₂, Ni(dmaeb)₂, Co(dmap)₂, Co(dmamp)₂, Co(emamp)₂, Co(deamp)₂, Co(emamb)₂, Co(deamb)₂, Co(dmaeb)₂, Cu(dmap)₂, Cu(dmamp)₂, Cu(emamp)₂, Cu(deamp)₂, Cu(emamb)₂, Cu(deamb)₂, Cu(dmaeb)₂, Fe(dmap)₂, Fe(dmamp)₂, Fe(emamp)₂, Fe(deamp)₂, Fe(emamb)₂, Fe(deamb)₂, Fe(dmaeb)₂, Mn(dmap)₂, Mn(dmamp)₂, Mn(emamp)₂, Mn(deamp)₂, Mn(emamb)₂, Mn(deamb)₂, Mn(dmaeb)₂, Cr(dmap)₂, Cr(dmamp)₂, Cr(emamp)₂, Cr(deamp)₂, Cr(emamb)₂, Cr(deamb)₂, Cr(dmaeb)₂, Zn(dmap)₂, Zn(dmamp)₂, Zn(emamp)₂, Zn(deamp)₂, Zn(emamb)₂, Zn(deamb)₂ and Zn(dmaeb)₂.

In some embodiments, the metal precursor is selected from the group consisting of Ni(dmap)2, Co(dmamp)2, Ni(dmamp)2, Co(dmaeb)2 and Cu(dmap)2.

In some embodiments, the deposited material comprises a transition metal.

In some embodiments, the deposited material comprises a transition metal selected from copper, nickel, iron, manganese, chromium, zinc and cobalt.

In some embodiments, the deposited material consists substantially of elemental metal.

In some embodiments, the noble metal is selected from the group consisting of ruthenium, platinum, iridium, palladium and rhodium.

In some embodiments, the second material comprises a material selected from the group consisting of silicon oxide, low-k material cobalt, tungsten, aluminum oxide, zirconium oxide, hafnium oxide.

In some embodiments, the material comprising metal or metal layer is formed at a temperature from about 120° C. to 200° C.

In some embodiments, the deposited material has a resistivity of 1.80 to 2.20 μΩcm.

In some embodiments, the deposition process is a single-source chemical vapor deposition process.

In a second aspect, device structure including the material comprising metal formed according to the method disclosed herein is disclosed.

In a third aspect, a vapor deposition assembly for depositing a material comprising metal on a substrate is disclosed. The vapor deposition assembly comprises one or more reaction chambers constructed and arranged to hold a substrate comprising a first surface and a second surface, the first surface comprising a first material and the second surface comprising a second material, a precursor injector system constructed and arranged to provide a metal precursor in the reaction chamber, a metal precursor source vessel constructed and arranged to hold a metal precursor in fluid communication with the reaction chamber. The metal precursor comprises metal aminoalkoxide and the first material comprises a noble metal.

In some embodiments, the first material consists substantially of noble metal.

### BRIEF DESCRIPTION OF THE DRAWING FIGURES

The accompanying drawings, which are included to provide a further understanding of the disclosure and constitute a part of this specification, illustrate exemplary embodiments, and together with the description help to explain the principles of the disclosure. In the drawings

FIG. 1 presents a flow chart of an exemplary embodiment of a method according to the current disclosure.

FIGS. 2A and 2B are schematic presentations of an exemplary embodiment of a method according to the current disclosure.

FIG. 3 is a schematic presentation of a vapor deposition assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In one aspect, a method of selectively depositing material comprising metal on a substrate by a cyclic deposition process is disclosed. In various methods according to the current disclosure, a substrate is provided in a reaction chamber. In other words, a substrate is brought into space where the deposition conditions can be controlled. The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously. In some embodiments, the reaction chamber is a multi-station reaction chamber.

As used herein, the term substrate may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, one or more transition metals, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers.

The substrate according to the current disclosure comprises two surfaces, i.e. a first surface comprising a first material and a second surface comprising a second material. The material comprising metal and the metal layer according to the current disclosure are deposited on the first surface relative to the second surface. The substrate may comprise any number of additional surfaces. The first surface and the second surface may be arranged as any suitable pattern. For example, the first surface and the second surface can be alternating lines or one surface can surround the other surface in a plan view. The first and section surfaces can be coplanar, the first surface may be raised relative to the second surface, or the second surface can be raised relative to the first surface. The first and second surfaces may be formed using one or more reaction chambers.

The first surface and the second surface comprise a first material and a second material, respectively. Thus, they may have different material properties. In some embodiments the first surface and the second surface are adjacent to each other. The first surface and the second surface may be on the same level or one of the surfaces may be lower than the other. In some embodiments, the first surface is lower than the second surface. For example, in some embodiments, the first surface may be etched to be positioned lower than the second surface. In some embodiments, the second surface may be etched to be positioned lower than the first surface. Alternatively or in addition, the materials of the first surface and the second surface may be deposited as to position the first surface and the second surface on different levels.

The substrate may comprise additional material or surfaces in addition to the first surface and the second surface. The additional material may be positioned between the first surface and the substrate, or between the second surface and the substrate, or between both the first and the second surface and the substrate. The additional material may form additional surfaces on the substrate.

In some embodiments, the first surface comprises noble metal material. In some embodiments, the first surface consists essentially of, or consists of, noble metal material. In some embodiments, the first surface comprises a material selected from the group consisting of copper, ruthenium, platinum, iridium, palladium, osmium and rhodium. In some embodiments, the first surface comprises, consists essentially of, or consists of ruthenium. In some embodiments, the first surface comprises, consists essentially of, or consists of platinum. In some embodiments, the first surface comprises, consists essentially of, or consists of copper. In some embodiments, the first surface comprises, consists essentially of, or consists of iridium. In some embodiments, the first surface comprises, consists essentially of, or consists of palladium. In some embodiments, the first surface comprises, consists essentially of, or consists of rhodium. In some embodiments, the first surface comprises, consists essentially of, or consists of osmium.

The second surface according to the current disclosure comprises a second material, and is the no-growth surface relative to the first surface. In other words, the material comprising a metal is not deposited, or is deposited to a lesser extent, on the second surface relative to the first surface.

In some embodiments, the second surface comprises a dielectric material. In some embodiments, the second surface consists essentially of, or consists of, a dielectric material. In some embodiments, the dielectric material of the second surface is low k material. In some embodiments, the dielectric material of the second surface comprises silicon. In some embodiments, the dielectric material of the second surface comprises silicon and oxygen. The second surface may comprise, consist essentially of, or consist of silicon oxide.

In some embodiments, the second surface comprises a metal. In some embodiments, the second surface consists essentially of, or consists of, a metal. Thus, in some embodiments, the second surface is a metal or metallic surface. In some embodiments, the second surface comprises elemental metal or metal alloy. In some embodiments, the second surface comprises electrically conductive material. In some embodiments, the second surface consists essentially of, or consist of conductive material. In some embodiments, the second surface comprises an elemental metal selected from late row 4 transition metals. In some embodiments, the metal of the second surface comprising elemental metal is selected from Sc, Y, Ti, Zr, Hf, V, Nb, Ta, Cr, Mo, W, Mn, Fe, Co, Ni, Zn, Al, Ga and In. In some embodiments, the second surface comprises, consists essentially of, or consists of copper (Cu). In some embodiments, the second surface comprises, consists essentially of, or consists of nickel (Ni). In some embodiments, the second surface comprises, consists essentially of, or consists of cobalt (Co). In some embodiments, the second surface comprises, consists essentially of, or consists of zinc (Zn). In some embodiments, the second surface comprises, consists essentially of, or consists of tungsten (W). In some embodiments, the second surface comprises, consists essentially of, or consists of yttrium (Y). In some embodiments, the second surface comprises, consists essentially of, or consists of scandium (Sc). In some embodiments, the second surface comprises, consists essentially of, or consists of titanium (Ti). In some embodiments, the second surface comprises, consists essentially of, or consists of Zr. In some embodiments, the second surface comprises, consists essentially of, or consists of Hf. In some embodiments, the second surface comprises, consists essentially of, or consists of vanadium (V). In some embodiments, the second surface comprises, consists essentially of, or consists of niobium (Nb). In some embodiments, the second surface comprises, consists essentially of, or consists of tantalum (Ta). In some embodiments, the second surface comprises, consists essentially of, or consists of chromium (Cr). In some embodiments, the second surface comprises, consists essentially of, or consists of molybdenum (Mo). In some embodiments, the second surface comprises, consists essentially of, or consists of manganese (Mn). In some embodiments, the second surface comprises, consists essentially of, or consists of iron (Fe). In some embodiments, the second surface comprises, consists essentially of, or consists of aluminum (Al). In some embodiments, the second surface comprises, consists essentially of, or consists of gallium (Ga). In some embodiments, the second surface comprises, consists essentially of, or consists of indium (In). In some embodiments, the metal of the second surface comprises elemental metal. In some embodiments, the second surface comprises a row 4 transition metal. In some embodiments, the second surface comprises a group 4 to 6 transition metal. In some embodiments, the second surface does not comprise Sc. In some embodiments, the second surface does not comprise Y. In some embodiments, the second surface does not comprise Ti. In some embodiments, the second surface does not comprise Zr. In some embodiments, the second surface does not comprise Hf. In some embodiments, the second surface does not comprise V. In some embodiments, the second surface does not comprise Nb. In some embodiments, the second surface does not comprise Ta. In some embodiments, the second surface does not comprise Cr. In some embodiments, the second surface does not comprise Mo. In some embodiments, the second surface does not comprise W. In some embodiments, the second surface does not comprise Mn. In some embodiments, the second surface does not comprise Fe. In some embodiments, the second surface does not comprise Co. In some embodiments, the second surface does not comprise Ni. In some embodiments, the second surface does not comprise Cu. In some embodiments, the second surface does not comprise Zn. In some embodiments, the second surface does not comprise Al. In some embodiments, the second surface does not comprise Ga. In some embodiments, the second surface does not comprise In. In some embodiments, the second surface does not comprise a row 4 transition metal. In some embodiments, the second surface does not comprise a group 4 to 6 transition metal. In some embodiments, the second surface consists essentially of, or consists of, elemental metal or an alloy of elemental metals. An elemental metal surface may comprise surface oxidation.

The second surface may comprise, consist essentially of, or consist of, a dielectric material. Examples of possible dielectric materials include metal oxide-based materials. In some embodiments the dielectric material comprises a metal oxide. In some embodiments, the dielectric material of the second surface is a high k material. In some embodiments, the dielectric material of the second surface is selected from aluminum oxide, tantalum oxide, hafnium oxide, zirconium oxide, hafnium zirconate, titanium oxide, yttrium oxide, lanthanum oxide, scandium oxide, strontium titanate, barium titanate, barium strontium titanate and magnesium oxide, erbium oxide, niobium oxide or a combination thereof. In the current disclosure, aluminum oxide may be, for example, Al₂O₃, tantalum oxide Ta₂O₅, hafnium oxide HfO₂, zirconium oxide ZrO₂, hafnium zirconate HfZrO₄, or Hf₁₋ₓZrₓO₂, titanium oxide TiO₂, yttrium oxide Y₂O₃, lanthanum oxide La₂O₃, scandium oxide ScO₂, strontium titanate SrTiO₃, barium titanate BaTiO₃, barium strontium titanate Ba_{0.5}Sr_{0.5}TiO₃, or BₐₓSr₁₋ₓTiO₃, magnesium oxide MgO, erbium oxide Er₂O₃ and niobium oxide Nb₂O₅. In some embodiments, the second surface may comprise ferroelectric material, such as HfZrO₂ (in various proportions of Hf and Zr). In some embodiments, the second material comprises non-ferroelectric hafnium zirconate. The dielectric material of the second surface, such as a metal oxide, may comprise doped material. The dopant may be suitable material, such as H, Si, Hf, Ti, Zr, or Nb.

In some embodiments, the dielectric material is a low k material, such as SiOC. In some embodiments, the second surface comprises SiOC. Without limiting the current disclosure to any specific theory, material referred to as SiOC may or may not comprise carbide bonds. The term SiOC is to be understood as material comprising silicon, oxygen and carbon. SiOC comprised in the second surface may comprise methyl groups. In some embodiments, the second surface comprises silicon-containing material comprising silicon-carbon bonds. In some embodiments, the second surface comprises silicon-containing material comprising
methyl groups. In some embodiments, the second surface comprises silicon-containing material comprising methyl groups and oxygen.

The current disclosure relates to a selective deposition process. By appropriately selecting the deposition conditions, material comprising metal may be selectively deposited on the first surface relative to the second surface. The methods according to the current disclosure may be performed without pre-treatments, such as passivation or other surface treatments to bring about selectivity. Thus, in some embodiments of the methods presented in the current disclosure, the deposition is inherently selective. However, as is understood by the skilled person, selectivity may be improved by processes such as cleaning of substrate surface, selective etching or the like.

Selectivity can be given as a percentage calculated by [(deposition on first surface)−(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

In some embodiments, deposition substantially only, or only, occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 30% selective, which may be selective enough for some particular applications. In some embodiments the deposition on the first surface of the substrate relative to the second surface of the substrate is at least about 10% selective, which may be selective enough for some particular applications.

In some embodiments, selective deposition is inherent, and no additional processing steps over those conveniently performed on a substrate are necessary. However, in some embodiments, the second surface may be passivated before depositing the material comprising molybdenum on the first surface. Selectivity may be inherent to a certain thickness of deposited material, and be lost in case deposition is continued beyond a process-specific threshold. Thus, it may be possible to deposit a material layer of, for example, about 1 nm, about 2 nm, about 3 nm, about 5 nm or about 6 nm before selectivity is lost. If thicker material layers are desired, the contrast between the first surface and the second surface may be enhanced though passivating the second surface. Alternatively or in addition, intermittent etch-back phase using, for example plasma, such as hydrogen plasma, may be used to keep selectivity.

In some embodiments the material comprising metal deposited on the first surface of the substrate may have a thickness of more than about 50 nm, more than about 20 nm, more than about 10 nm, more than about 5 nm, more than about 3 nm, more than about 2 nm, or more than about 1 nm, while there is substantially no deposition on the second surface. In some embodiments, minor, island-like, deposition may be detectable on the second surface, while a continuous material layer is deposited on the first surface. In some embodiments, a ratio of material comprising metal deposited on the first surface of the substrate relative to the second surface of the substrate may be greater than or equal to about 2:1, greater than or equal to about 20:1, greater than or equal to about 200:1, For example, ratio of material comprising metal deposited on the first surface of the substrate relative to the second surface of the substrate may be about 150:1, about 100:1, about 50:1, about 20:1, about 15:1, about 10:1, about 5:1, about 3:1, or about 2:1.

In some embodiments, a substantially continuous metal layer having a thickness of at least 10 nm is deposited on a first surface with substantially no deposition on the second surface. In some embodiments, a substantially continuous metal layer having a thickness of at least 15 nm is deposited on a first surface with substantially no deposition on the second surface. In some embodiments, a substantially continuous metal layer having a thickness of at least 20 nm is deposited on a first surface with substantially no deposition on the second surface. In some embodiments, a substantially continuous metal layer having a thickness of at least 25 nm is deposited on a first surface with substantially no deposition on the second surface.

In some embodiments, selectivity of the selective deposition processes described herein may depend on the materials which comprise the first and/or second surface. For example, in some embodiments, where the first surface comprises noble metal, such as ruthenium and the second surface comprises a dielectric, such as silicon oxide, the selectivity may be greater than about 10:1 or greater than about 20:1.

A material comprising metal is deposited using a cyclic deposition process. Thus, the method comprises providing a metal aminoalkoxide precursor in the reaction chamber in vapor phase to deposit a material comprising metal on the first surface relative to the second surface. Providing a metal aminoalkoxide precursor in the reaction chamber may constitute a deposition cycle. A deposition cycle may be performed at least once during a deposition process. In some embodiments, a deposition cycle is repeated one or more times. For example, a deposition cycle may be performed from 2 to 2,000 times, such as about 50, about 100, about 500, about 800, about 1,000 or about 1,500 times. A deposition cycle may comprise additional phases, such as purging between cycles, or providing additional precursor(s) or reactant(s) in the reaction chamber. The deposition cycles may be substantially similar, or the process may comprise two or more different types of deposition cycles, such as differing in the length of providing a precursor or a reactant in the reaction chamber, purge time or deposition temperature.

As used herein, the term “cyclic deposition” may refer to the sequential introduction of precursors (reactants) into a reaction chamber to deposit a layer over a substrate, and it includes processing techniques such as atomic layer deposition (ALD) and cyclic chemical vapor position (cyclic CVD). CVD type processes typically involve gas phase reactions between two or more precursors. In some cases the precursor(s) decompose on the substrate surface to produce the desired deposit. The precursors may be provided simultaneously to a reaction chamber containing a substrate on which material is to be deposited. The precursors may be provided in partially or completely separated pulses. In some cases, a CVD type process may be a single source CVD process in which a single precursor is provided into the reaction chamber. In some embodiments, the deposition process is single source CVD process. In this process the first surface acts as a catalyst for thermal decomposition of the precursor.

The substrate and/or reaction chamber can be heated to promote the reaction of the gaseous precursor(s). In some embodiments, the precursor(s) is/are provided until a layer having a desired thickness is deposited. In some embodiments, cyclic CVD type processes can be used with multiple cycles to deposit a thin material having a desired thickness. In cyclic CVD-type processes, the precursor(s) may be provided to the reaction chamber in pulses that do not overlap, or that partially or completely overlap.

ALD-type processes are based on controlled, typically self-limiting surface reactions of precursors. Vapor phase reactions are avoided by feeding the precursors alternately and sequentially into the reaction chamber. Vapor phase precursors are separated from each other in the reaction chamber, for example, by removing excess precursors and/or reaction by-products from the reaction chamber between precursor pulses. This may be accomplished with an evacuation step and/or with an inert gas pulse or purge. In some embodiments the substrate is contacted with a purge gas, such as an inert gas. For example, the substrate may be contacted with a purge gas between precursor pulses to remove excess precursor and reaction by-products.

In some embodiments of the current disclosure the process may operate in a process condition regime close to CVD conditions or in some cases fully in CVD conditions.

Purging means that vapor phase precursors and/or vapor phase byproducts are removed from the substrate surface such as by evacuating the reaction chamber with a vacuum pump and/or by replacing the gas inside a reaction chamber with an inert gas such as argon or nitrogen. In some embodiments, the reaction chamber is purged after providing a metal aminoalkoxide precursor in the reaction chamber. Purging may be performed between two precursor pulses. Typical purging times are from about 0.05 to 20 seconds, and can be about 0.2 and 10, or between about 0.5 and 5 seconds. However, other purge times can be utilized if necessary, such as where highly conformal step coverage over extremely high aspect ratio structures or other structures with complex surface morphology is needed, or where different reactor types may be used, such as a batch reactor. As described above for ALD, purging may be performed in a temporal or in a spatial mode.

In this disclosure, “gas” can include material that is a gas at normal temperature and pressure (NTP), a vaporized solid and/or a vaporized liquid, and can be constituted by a single gas or a mixture of gases, depending on the context. The term “inert gas” can refer to a gas that does not take part in a chemical reaction to an appreciable extent. Exemplary inert gases include He and Ar and any combination thereof. In some cases, nitrogen and/or hydrogen can be an inert gas. A gas other than the process gas, i.e., a gas introduced without passing through a gas distribution assembly, other gas distribution device, or the like, can be used for, e.g., sealing the reaction space, and can include a seal gas, such as a rare gas.

The term “precursor” can refer to a compound that participates in the chemical reaction that produces another compound, and particularly to a compound that constitutes deposited material. The term “reactant” can be used interchangeably with the term precursor. However, a reactant may be used for chemistries that modify deposited material.

In some embodiments, the method according to the current disclosure is a thermal deposition method. A thermal deposition method is to be understood as a method, in which precursors and reactants are not activated by plasma. However, in some embodiments, the method may comprise one or more plasma activation steps. Such processes may be termed plasma processes, although they may include thermal deposition steps as well.

In the methods according to the current disclosure, material comprising metal is deposited. In some embodiments, the material comprising metal consists essentially of, or consists of, one or more transition metals. In some embodiments, the deposited metal is selected from a group consisting of copper, nickel, iron, manganese, chromium, zinc and cobalt. In some embodiments, the deposited metal is selected from a group consisting of copper, nickel and cobalt. In some embodiments, the deposited material comprising a metal consists substantially of, or consists of, copper. In some embodiments, the deposited material comprising a metal consists substantially of, or consists of, nickel. In some embodiments, the deposited material comprising a metal consists substantially of, or consists of, cobalt.

In some embodiments, material comprising metal deposited according to the current disclosure may form a layer. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous. Thus, the material comprising metal may form a layer on the first surface of the substrate. In some embodiments, the layer comprising a metal may be substantially or fully

continuous. In some embodiments, the layer comprising a metal is substantially or fully pinhole-free. In some embodiments, the layer comprising a metal is substantially pinhole-free at a thickness below about 50 nm. In some embodiments, the layer comprising a metal is substantially pinhole-free at a thickness below about 20 nm. In some embodiments, the layer comprising a metal is substantially pinhole-free at a thickness below about 10 nm. In some embodiments, the layer comprising a metal is substantially pinhole-free at a thickness below about 7 nm. In some embodiments, the layer comprising a metal is substantially pinhole-free at a thickness below about 5 nm. In some embodiments, the layer comprising a metal consists substantially of, or consists of, one metal. In some embodiments, the layer comprising a metal consists substantially of, or consists of, two or more metals. A material may be considered to consist of a metal despite containing an acceptable amount of impurities.

In some embodiments, a material and a layer comprising metal may comprise, for example, from about 50 to about 99.5 at. % metal, or from about 70 to about 99.5 at. % metal, or from about 85 to about 99.5 at. % metal, or from about 90 to about 99.5 at. % metal. A material comprising metal deposited by a method according to the current disclosure may comprise, for example about 30 at. %, about 50 at. %, about 70 at. %, about 80 at. %, about 83 at. %, about 85 at. %, about 87 at. %, about 90 at. %, about 95 at. %, about 97 at. % or about 99 at. % metal. In some embodiments, the material comprising metal deposited according to the current disclosure comprises less than about 3 at. %, or less that about 1 at. % IMPURITY X. In some embodiments, the material comprising metal deposited according to the current disclosure comprises less than about 5 at. %, less than about 3 at. %, less that about 1 at. % or less that about 0.5 at. % oxygen. In some embodiments, the material comprising metal deposited according to the current disclosure comprises less than about 3 at. %, or less that about 2 at. %, or less that about 1 at. %, or less that about 0.5 at. % carbon. In some embodiments, the metal-containing material deposited according to the current disclosure comprises less than about 2.5 at. %, less that about 2 at. %, less that about 1 at. % or less that about 0.1 at. % hydrogen. In some embodiments, the metal-containing material deposited according to the current disclosure comprises less than about 2.5 at. %, less that about 2 at. %, less that about 1 at. % or less that about 0.1 at. % nitrogen. In some embodiments, the material comprising metal deposited according to the current disclosure contains less than about 6 at. %, or less than about 3 at. %, or less than about 1 at. % of impurities.

In some embodiments, material comprising metal or a layer comprising a metal may be deposited by a cyclic deposition process using a metal aminoalkoxide precursor. In some embodiments, the metal aminoalkoxide precursor consists substantially of, or consists of the metal aminoalkoxide compound. A metal aminoalkoxide compound comprises a metal atom and an aminoalkoxide ligand. In some embodiments, an aminoalkoxide ligand is a monodentate ligand. In some embodiments, an aminoalkoxide ligand is a bidentate ligand.

In some embodiments, the metal aminoalkoxide comprises an amino group and an alkoxide group. In some embodiments, the amino group and the alkoxide group are bonded to the metal.

In some embodiments, the aminoalkoxide is selected from the group consisting of 1-dimethylamino-2-propoxide (dmap), 1-dimethylamino-2-methyl-2-propoxide (dmamp), 1-ethylmethylamino-2-methyl-2-propoxide (emamp), 1-diethylamino-2-methyl-2-propoxide (deamp), 1-ethylmethylamino-2-methyl-2-butoxide (emamb), 1-dimethylamino-2-methyl-2-butoxide (dmamb), 1-dimethylamino-2-ethyl-2-butoxide (dmaeb), and 1-diethylamino-2-methyl-2-butoxide (deamb).

In some embodiments the metal aminoalkoxide precursor is selected from the group consisting of Ni(dmap)₂, Ni(dmamp)₂, Ni(emamp)₂, Ni(deamp)₂, Ni(emamb)₂, Ni(deamb)₂, Ni(dmamb)₂, Ni(dmaeb)₂, Co(dmap)₂, Co(dmamp)₂, Co(emamp)₂, Co(deamp)₂, Co(emamb)₂, Co(deamb)₂, Co(dmamb)₂, Co(dmaeb)₂, Cu(dmap)₂, Cu(dmamp)₂, Cu(emamp)₂, Cu(deamp)₂, Cu(emamb)₂, Cu(deamb)₂, Cu(dmamb)₂, Cu(dmaeb)₂, Fe(dmap)₂, Fe(dmamp)₂, Fe(emamp)₂, Fe(deamp)₂, Fe(emamb)₂, Fe(deamb)₂, Fe(dmamb)₂, Fe(dmaeb)₂, Mn(dmap)₂, Mn(dmamp)₂, Mn(emamp)₂, Mn(deamp)₂, Mn(emamb)₂, Mn(deamb)₂, Mn(dmamb)₂, Mn(dmaeb)₂, Cr(dmap)₂, Cr(dmamp)₂, Cr(emamp)₂, Cr(deamp)₂, Cr(emamb)₂, Cr(deamb)₂, Cr(dmamb)₂, Cr(dmaeb)₂, Zn(dmap)₂, Zn(dmamp)₂, Zn(emamp)₂, Zn(deamp)₂, Zn(emamb)₂, Zn(dmaeb)₂, Zn(deamb)₂ and Zn(dmamb)₂.

In some embodiments, the metal aminoalkoxide precursor is selected from the group consisting of Ni(dmap)₂, Co(dmamp)₂, Ni(dmamp)₂, Co(dmaeb)₂ and Cu(dmap)₂.

When a metal aminoalkoxide precursor is provided in the reaction chamber, it contacts the substrate. The metal aminoalkoxide precursor may be provided in the reaction chamber for a time period of between about 0.01 seconds and about 90 seconds, between about 0.05 second sand about 60 seconds, between about 0.05 seconds and about 45 seconds, between about 0.05 seconds and about 30 seconds, between about 0.05 seconds and about 15 seconds, between about 0.05 seconds and about 10 seconds or between about 0.05 seconds and about 5 seconds. In some embodiments, the metal aminoalkoxide precursor is provided in the reaction chamber for a time period of between about 0.5 seconds and about 5 seconds, between about 1 second and about 5 seconds, between about 1.5 seconds and about 5 seconds, between about 2 seconds and about 5 seconds. For example, the metal aminoalkoxide precursor may be provided in the reaction chamber for about 0.5 seconds, for about 1 second, for about 1.5 seconds, for about 2 seconds or for about 3 seconds. The pulsing time may depend on the flow rate of the precursors and carrier gases into the reaction chamber. The flow rates of process gases may depend on the specifics of the deposition assembly used for performing the current methods, and may thus be adjusted together or separately from the pulse time.

Excess metal aminoalkoxide precursor and reaction byproducts (if any) may be removed from the substrate surface, e.g., by pumping with an inert gas. For example, in some embodiments of the disclosure, the methods may comprise a purge wherein the substrate surface is purged for a time period of less than approximately 2 seconds. Excess metal amiunoalkoxide precursor and any reaction byproducts may be removed with the aid of a vacuum, generated by a pumping system, in fluid communication with the reaction chamber. Purging gas is preferably any inert gas, such as, without limitation, argon (Ar), nitrogen (N2), helium (He), or in some instances hydrogen (H2) could be used. A phase is generally considered to immediately follow another phase if a purge (i.e., purging gas pulse) or other precursor, reactant or by-product removal step intervenes.

The cyclic deposition processes described herein, utilizing a metal aminoalkoxide precursor to deposit a metal-containing material, may be performed in an ALD or CVD deposition system with a heated substrate. The deposited material may be considered to form at the substrate temperature. In some embodiments, the material comprising metal or metal layer is formed at a temperature from about 100° C. to about 225° C. For example, in some embodiments, methods may comprise heating the substrate to temperature of between approximately 110° C. and approximately 200° C., or even heating the substrate to a temperature of between approximately 115° C. and approximately 190° C. The appropriate temperature window for any given cyclic deposition process, such as, for an CVD reaction, will depend upon the surface termination and precursor species involved. Here, the temperature varies depending on the precursors being used and is generally at or below about 200° C. In some embodiments, the deposition temperature is generally at or above about 100° C. for vapor deposition processes, in some embodiments the deposition temperature is between about 130° C. and about 180° C.

In some embodiments, the growth rate of the metal containing material is from about 0.01 A/cycle to about 5 A/cycle, or from about 0.01 A/cycle to about 2 A/cycle. In some embodiments the growth rate of the metal containing material is higher than about 0.05 A/cycle, higher than about 0.1 A/cycle, higher than about 0.15 A/cycle, higher than about 0.2 A/cycle, higher than about 0.25 A/cycle, or higher than about 0.3 A/cycle. In some embodiments the growth rate of the metal containing material is lower than about 3 A/cycle, lower than about 2 A/cycle, lower than about 1 A/cycle, lower than about 0.5 A/cycle, or lower than about 0.2 A/cycle. In some embodiments, the growth rate of the metal containing material may be approximately 0.4 A/cycle.

In some embodiments, the method comprises cleaning the substrate before providing the metal precursor in the reaction chamber, and/or before providing the reactant in the reaction chamber. In some embodiments, cleaning the substrate comprises contacting the substrate with a cleaning agent. In some embodiments, the cleaning agent comprises a chemical selected from β-diketonates, cyclopentadienyl-containing chemicals, carbonyl-containing chemicals, carboxylic acids and hydrogen. In some embodiments, the substrate surface may be cleaned with plasma, such as hydrogen plasma.

In some embodiments, the method comprises activating the substrate before providing the metal aminoalkoxide precursor in the reaction chamber. In some embodiments, activating the substrate comprises exposing the substrate to UV radiation. For example UV radiation having a wavelength from about 180 to about 300 nm may be used. In some embodiments, the UV radiation has a wavelength of about 254 nm. The duration of an UV radiation-based activation depends on the intensity of the radiation, and may vary, for example, between about 1 second and about 5 min. In some embodiments, the duration of the UV treatment may be from about 5 seconds to about 5 minutes, or from about 5 seconds to about 1 minute, or from about 5 seconds to about 30 seconds, or from about 1 second to about 10 seconds.

In an aspect, a semiconductor device structure comprising material deposited according to the method presented herein is disclosed. As used herein, a “structure” can be or include a substrate as described herein. Structures can include one or more layers overlying the substrate, such as one or more layers formed according to a method according to the current disclosure.

In accordance with yet additional embodiments of the disclosure, a device, structure, or portion thereof can be formed by a method as described herein. In some embodiments, the device can include a substrate, an insulating or dielectric layer, a layer deposited by a method as described herein overlying the insulating or dielectric layer, and optionally an additional metal layer overlying the layer deposited by a method as described herein.

Optionally, a further layer, e.g., a metal layer, may be provided between the layer deposited by a method as described herein and the insulating or dielectric layer. in some embodiments, the device can be or form part of, for example, a MOSFET, e.g. a pMOSFET or an nMOSFET.

In some embodiments, the MOSFET device may be a PMOS field effect transistor. Thus, further provided is a PMOS field effect transistor comprising a threshold voltage tuning layer deposited by a method as described herein. Suitably, the threshold voltage shifting layer may be comprised in a gate electrode comprised in the field effect transistor

In some embodiments, the MOSFET device may be an NMOS field effect transistor Thus, further provided is an NMOS field effect transistor comprising a threshold voltage tuning layer deposited by a method as described herein Suitably, the threshold voltage shifting layer is comprised in a gate electrode comprised in the field effect transistor

In some embodiments, there is provided a gate-all-around field effect transistor It

comprises a gate contact comprising a layer formed according to a method as described herein.

In some embodiments, there is provided a MIM metal electrode comprising a layer deposited by a method as described herein.

In some embodiments, there is provided VNAND contact comprising a layer deposited by a method as described herein.

In some embodiments, there is provided a Dynamic random-access memory (DRAM) cell electrode comprising a layer formed by a method or apparatus as described herein.

The disclosure is further explained by the following exemplary embodiments depicted in the drawings. The illustrations presented herein are not meant to be actual views of any particular material, layer, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity. The illustrations presented herein are not meant to be actual views of any particular material, structure, or device, but are merely idealized representations that are used to describe embodiments of the disclosure.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

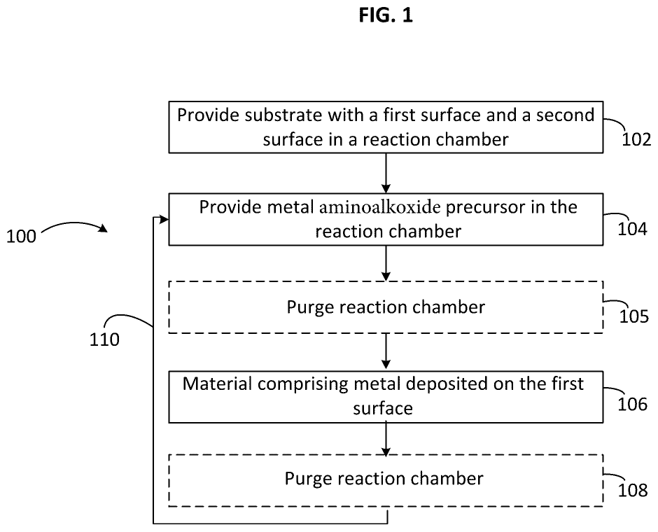

FIG. 1 presents a flow chart of an exemplary embodiment of a method according to the current disclosure.

The method 100 may begin with a process block 102 which comprises, providing a substrate in a reaction chamber. The substrate may be heated to a deposition temperature. For example, the substrate may comprise one or more partially fabricated semiconductor device structures. The reaction chamber may comprise a chemical vapor deposition reaction chamber, and the substrate may be heated to a deposition temperature. The deposition temperature may be, for example, from about 100° C. to about 200° C., such as about 125° C., about 150° C. or about 175° C. In addition, the pressure within the reaction chamber may be controlled. For example, the pressure within the reaction chamber during the cyclic deposition process may be less than about 100 Torr, less than about 50 Torr, less than about 10 Torr, less than about 5 Torr, or less than about 1 Torr.

The method 100 may continue with a process block 104, in which a metal aminoalkoxide precursor is provided in the reaction chamber. When a metal aminoalkoxide precursor is provided in the reaction chamber, the metal aminoalkoxide precursor may come into contact with the substrate for a time period (the pulse time) from about 0.05 seconds to about 60 seconds. In some embodiments, the metal aminoalkoxide compound may contact the substrate for a time period of between about 0.05 seconds and about 10 seconds, or between about 0.1 seconds and about 5 seconds. In addition, during the time for which the metal aminoalkoxide precursor is provided in the reaction chamber (i.e. pulse time), the flow rate of the metal aminoalkoxide precursor may be selected as appropriate, and be for example about or over 2,000 sccm, from about 1,000 sccm to about 2,000 sccm, or from about 500 sccm to about 1,000 sccm, or from about 200 sccm to about 500 sccm, or from about 100 sccm to about 500 sccm, or less than about 100 sccm.

The method 100 may continue with a process block 105 comprising purging the reaction chamber after metal aminoalkoxide precursor has been provided in the reaction chamber 104. In other words, after contacting the substrate with the metal aminoalkodie precursor at block 104, excess metal aminoalkoxide precursor and any reaction byproducts may be removed from the reaction chamber by a purge process. However, block 105 is optional, and in some embodiments, it is omitted.

Providing metal aminoalkoxide precursor (block 104) in the reaction chamber, and thereby decomposing it onto the substrate leads to the deposition of material comprising metal on the first surface (block 106). Although depicted as a separate block, the material comprising metal may be continuously formed as the precursor is provided in the reaction chamber. The actual rate of deposition and its kinetics may vary according to process specifics. Depending on the specific material being deposited, and the composition of the first surface and the second surface, the degree of selectivity of the process may vary.

At process block 108, the reaction chamber is purged after depositing the material comprising a metal. If the cyclic deposition process is repeated (loop 110), the second purge (108) may be followed by providing the metal aminoalkoxide precursor in the reaction chamber (104).

The exemplary cyclic deposition method 100 wherein material comprising metal is selectively deposited on the first surface of the substrate relative to the second surface of the substrate by alternatively and sequentially contacting the substrate with the metal precursor (process block 104) may constitute one deposition cycle. In some embodiments, the method of depositing a metal containing material may comprise repeating the deposition cycle one or more times (loop 110). The repetition of the deposition cycle is determined based on the thickness of the material comprising metal deposited. For example, if the thickness of the material

comprising metal is not sufficient for the desired device structure, then the method 100 may return to the process block 104 and the processes of contacting the substrate with the metal aminoalkoxide precursor 104 may be repeated one or more times (loop 110). Once the material comprising metal has been deposited to a desired thickness, the method may be stopped, and the material comprising metal and the underlying semiconductor structure may be subjected to additional processes to form one or more device structures.

In some embodiments, the material comprising a metal deposited according to methods described herein may be continuous on the first surface at a thickness below approximately 100 nm, or below approximately 60 nm, or below approximately 50 nm, or below approximately 40 nm, or below approximately 30 nm, or below approximately 25 nm, or below approximately 20 nm, or below approximately 15 nm, or below approximately 10 nm, or below approximately 5 nm, or lower. The continuity referred to herein can be physically continuity or electrical continuity. In some embodiments the thickness at which a material may be physically continuous may not be the same as the thickness at which a material is electrically continuous, and the thickness at which a material may be electrically continuous may not be the same as the thickness at which a material is physically continuous.

In some embodiments, a material comprising metal deposited according to some of the embodiments described herein may form a layer having a thickness from about 10 nm to about 100 nm. In some embodiments, a material comprising metal deposited according to some of the embodiments described herein may form a layer having a thickness from about 1 nm to about 10 nm. In some embodiments, the material comprising metal may form a layer having a thickness of less than 10 nm. In some embodiments, a material comprising metal deposited according to some of the embodiments described herein may form a layer having a thickness from about 10 nm to about 50 nm. In some embodiments, a metal containing material deposited according to some of the embodiments described herein may form a layer having a thickness greater than about 20 nm, or greater than about 40 nm, or greater than about 40 nm, or greater than about 50 nm, or greater than about 60 nm, or greater than about 100 nm, or greater than about 250 nm, or greater than about 500 nm. In some embodiments, a material comprising metal deposited according to some of the embodiments described herein may form a layer having a thickness of less than about 50 nm, less than about 30 nm, less than about 20 nm, less than about 15 nm, less than about 10 nm, less than about 5 nm, less than about 3 nm, less than about 2 nm, or even less than about 1 nm.

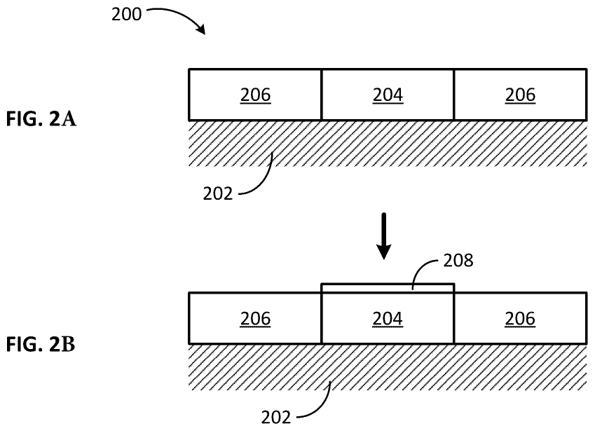

FIGS. 2A and 2B illustrate a partially fabricated semiconductor device structure 200 as a simplified schematic illustration. As depicted in FIG. 2A, the structure 200 comprises a substrate 202 and a first surface 204 formed over the substrate 202. The first surface 204 may comprise a noble metal-containing material, such as ruthenium. The structure further comprises a second surface 206 formed in the figure on each side of the first surface 204. In some embodiments, the second surface 206 may comprise one or more of silicon oxide, low-k material, cobalt, tungsten, aluminum oxide, zirconium oxide, hafnium oxide.

FIG. 2B illustrates the partially fabricated semiconductor device after a layer comprising metal 208 has been deposited on the first surface.

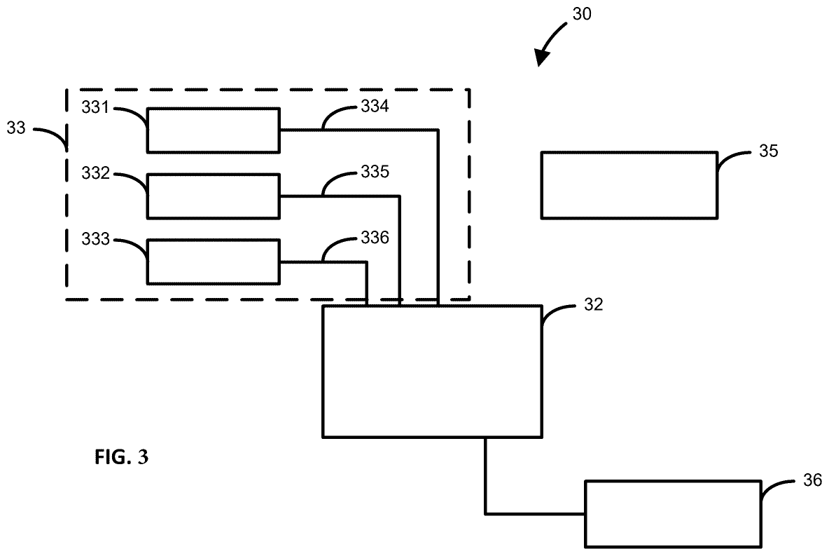

FIG. 3 is a schematic presentation of a vapor deposition assembly 30 according to the current disclosure. Deposition assembly 330 can be used to perform a method as described herein and/or to form a structure or a device, or a portion thereof as described herein.

In the illustrated example, deposition assembly 30 includes one or more reaction chambers 32, a precursor injector system 33, a metal aminoalkoxide precursor vessel 331, an optional reactant vessel 332, an optional purge gas source 333, an exhaust source 34, and a controller 35.

Reaction chamber 32 can include any suitable reaction chamber, such as an ALD or CVD reaction chamber.

The metal aminoalkoxide precursor vessel 331 can include a vessel and one or more metal aminoalkoxide precursors as described herein-alone or mixed with one or more carrier (e.g., inert) gases. The optional reactant vessel 332 can include a vessel and a reactant according to the current disclosure-alone or mixed with one or more carrier gases. The optional purge gas source 333 can include one or more inert gases as described herein. Although illustrated with three source vessels 331-333, deposition assembly 30 can include any suitable number of source vessels. Source vessels 331-333 can be coupled to reaction chamber 32 via lines 334-336, which can each include flow controllers, valves, heaters, and the like. In some embodiments, the metal aminoalkoxide precursor in the precursor vessel may be heated. In some embodiments, the vessel is heated so that the metal aminoalkoxide precursor reaches a temperature between about 100° C. and about 225° C., such as between about 120° C. and about 200° C., or between about 120° C. and about 185° C., for example 130° C., 140° C., 160° C., 165° C., or 180° C.

Exhaust source 34 can include one or more vacuum pumps.

Controller 35 includes electronic circuitry and software to selectively operate valves, manifolds, heaters, pumps and other components included in the deposition assembly 30. Such circuitry and components operate to introduce precursors, reactants and purge gases from the respective sources 331-333. Controller 35 can control timing of gas pulse sequences, temperature of the substrate and/or reaction chamber 32, pressure within the reaction chamber 32, and various other operations to provide proper operation of the deposition assembly 30. Controller 35 can include control software to electrically or pneumatically control valves to control flow of precursors, reactants and purge gases into and out of the reaction chamber 32. Controller 35 can include modules such as a software or hardware component, which performs certain tasks. A module may be configured to reside on the addressable storage medium of the control system and be configured to execute one or more processes.

Other configurations of deposition assembly 30 are possible, including different numbers and kinds of precursor sources and purge gas sources. Further, it will be appreciated that there are many arrangements of valves, conduits, precursor sources, and purge gas sources that may be used to accomplish the goal of selectively and in coordinated manner feeding gases into reaction chamber 32. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 30, substrates, such as semiconductor wafers (not illustrated), are transferred from, e.g., a substrate handling system to reaction chamber 32. Once substrate(s) are transferred to reaction chamber 32, one or more gases from gas sources 331-333, such as precursors, reactants, carrier gases, and/or purge gases, are introduced into reaction chamber 32 to effect a method according to the current disclosure.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for selectively depositing material comprising metal on a substrate by a cyclic deposition process, the method comprising:
providing a substrate in a reaction chamber, wherein the substrate comprises a first surface comprising a first material, and a second surface comprising a second material; and
providing a metal aminoalkoxide precursor into the reaction chamber in vapor phase to deposit a material comprising a metal on the first surface relative to the second surface,
wherein the metal aminoalkoxide precursor comprises an amino group and an alkoxide group, and
wherein the first material comprises a noble metal.

2. The method according to claim 1, wherein the metal in the metal aminoalkoxide precursor is a transition metal.

3. The method according to claim 2, wherein the transition metal is selected from the group consisting of copper, nickel, iron, manganese, chromium, zinc and cobalt.

4. The method according to claim 1, wherein the metal aminoalkoxide precursor is a bidentate ligand.

5. The method according to claim 1, wherein the amino group and the alkoxide group are bonded to the metal.

6. The method according to claim 1, wherein the metal aminoalkoxide precursor comprises at least one aminoalkoxide ligand.

7. The method according to claim 1, wherein the metal aminoalkoxide precursor comprises two aminoalkoxide ligands.

8. The method according to claim 1, wherein the metal aminoalkoxide precursor comprises a ligand selected from the list consisting of dmap, dmamp, emamp, deamp, emamb, deamb and dmaeb.

9. The method according to claim 1, wherein the metal aminoalkoxide precursor is selected from the group consisting of Ni(dmap)₂, Ni(dmamp)₂, Ni(emamp)₂, Ni(deamp)₂, Ni(emamb)₂, Ni(deamb)₂, Ni(dmaeb)₂, Co(dmap)₂, Co(dmamp)₂, Co(emamp)₂, Co(deamp)₂, Co(emamb)₂, Co(deamb)₂, Co(dmaeb)₂, Cu(dmap)₂, Cu(dmamp)₂, Cu(emamp)₂, Cu(deamp)₂, Cu(emamb)₂, Cu(deamb)₂, Cu(dmaeb)₂, Fe(dmap)₂, Fe(dmamp)₂, Fe(emamp)₂, Fe(deamp)₂, Fe(emamb)₂, Fe(deamb)₂, Fe(dmaeb)₂, Mn(dmap)₂, Mn(dmamp)₂, Mn(emamp)₂, Mn(deamp)₂, Mn(emamb)₂, Mn(deamb)₂, Mn(dmaeb)₂, Cr(dmap)₂, Cr(dmamp)₂, Cr(emamp)₂, Cr(deamp)₂, Cr(emamb)₂, Cr(deamb)₂, Cr(dmaeb)₂, Zn(dmap)₂, Zn(dmamp)₂, Zn(emamp)₂, Zn(deamp)₂, Zn(emamb)₂, Zn(deamb)₂ and Zn(dmaeb)₂.

10. The method according to claim 1, wherein the metal aminoalkoxide precursor is selected from the group consisting of Ni(dmap)₂, Co(dmamp)₂, Ni(dmamp)₂, Co(dmaeb)₂ and Cu(dmap)₂.

11. The method according to claim 1, wherein the deposited material comprises a transition metal.

12. The method according to claim 1, wherein the deposited material comprises a transition metal selected from copper, nickel, iron, manganese, chromium, zinc and cobalt.

13. The method according to claim 1, wherein the deposited material consists substantially of elemental metal.

14. The method according to claim 1, wherein the noble metal is selected from the group consisting of ruthenium, platinum, iridium, palladium, osmium and rhodium.

15. The method according to claim 1, wherein second material comprises a material selected from the group consisting of silicon oxide, low-k material cobalt, tungsten, aluminum oxide, zirconium oxide, hafnium oxide.

16. The method according to claim 1, wherein the material comprising metal or metal layer is formed at a temperature from about 120° C. to 200° C.

17. The method according to claim 1, wherein the deposited material has a resistivity of 1.80 to 2.20 μΩcm.

18. The method according to claim 1, wherein the cyclic deposition process is a single source chemical vapor deposition process.

19. Vapor deposition assembly for depositing a material comprising metal on a substrate, the vapor deposition assembly comprising:
one or more reaction chambers constructed and arranged to hold a substrate comprising a first surface and a second surface, the first surface comprising a first material and the second surface comprising a second material;
a precursor injector system constructed and arranged to provide a metal precursor in the reaction chamber; and
a metal precursor source vessel constructed and arranged to hold a metal precursor in fluid communication with the reaction chamber,
wherein the metal precursor comprises metal aminoalkoxide and the first material comprises a noble metal.

20. The vapor deposition assembly according to claim 19, wherein the first material consists substantially of noble metal.
